(19) United States
(12) Patent Application Publication
(10) Pub. No.: US 2022/0350935 A1
(43) Pub. Date: Nov. 3, 2022

(54) PARTITION WALL DESIGN FOR UNIVERSAL BAY SYSTEM

(71) Applicant: Dell Products L.P., Round Rock, TX (US)

(72) Inventors: Stephen Strickland, Foxborough, MA (US); Jeffrey Michael Lewis, Maynard, MA (US); Kevin Warren Mundt, Austin, TX (US)

(21) Appl. No.: 17/243,231

(22) Filed: Apr. 28, 2021

(51) Int. Cl. G06F 30/10

(52) U.S. Cl. CPC G06F 30/10

(57) ABSTRACT

A universal bay system is configurable to accommodate multiple sets of devices having different form factors and maximizes space utilization. A partition may be assembled with two walls and may engage receivers in a first support plane, wherein two adjacent partitions form a bay. Each wall may be configured with device retainers to accommodate a set of processing, memory, I/O or storage devices of different form factors, power supply units (PSUs) or provide an airflow channel relative to a specific set of devices.

### BACKGROUND

### Field of the Disclosure

This disclosure relates generally to information handling systems and, more particularly, to a universal bay system configurable with partitions for supporting multiple sets of devices in bays in a chassis.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems for use as servers and data centers are typically assembled in chassis or other enclosures specifically manufactured for that information handling system.

### SUMMARY

Embodiments may be directed to a universal bay system and method for assembling a universal bay system for accommodating multiple sets of devices of an information handling system in a chassis. A universal bay system may comprise a pair of guide rails, a plurality of support planes connected to the pair of guide rails, and a plurality of partitions. A first support plane and an adjacent second support plane may be separated by a distance to form a row. Each partition comprises a first wall comprising a first wall connector and a support plane connector and a second wall comprising a second wall connector and a second support plane connector. The second wall connector engages the first wall connector to form the partition. Each partition is coupled to the first support plane and the second support plane to divide the row into a plurality of bays.

In some embodiments, a wall for a particular bay may be assembled with a device retainer configured to retain of a set of devices in the bay. The device retainer may comprise a plurality of device rails to allow a technician to slide a set of memory devices, processing devices, storage devices or networking devices into the bay.

In some embodiments, a bay is configured to retain a power supply unit (PSU) or is configured as a channel for airflow through the chassis.

### BRIEF DESCRIPTION OF THE DRAWINGS

For a more complete understanding of the invention and its features and advantages, reference is now made to the following description, taken in conjunction with the accompanying drawings, in which:

FIG. 1 is a perspective view of an embodiment of a universal bay system configurable to accommodate multiple sets of devices of an information handling system in a chassis;

FIGS. 2A-2C are perspective views illustrating a method for assembling a partition from two walls;

FIGS. 3A-3B are perspective views illustrating a method for positioning a partition on a support plane of the chassis of FIG. 1;

FIG. 4 is a perspective view of a portion of a bay formed on a support plane of the chassis of FIG. 1; and

FIG. 5 is a perspective view of a portion of the bay formed on the support plane of the chassis of FIG. 4 with retaining features coupled to two walls;

FIGS. 6A-6B are perspective views illustrating a method for positioning and coupling a second support plane to the partition of FIG. 5 with a set of devices positioned in the bay;

FIG. 6C is a partial perspective view of the chassis of FIG. 6B, illustrating a mechanism for coupling the second support plane to a partition; and

FIG. 7 is a perspective view of a chassis formed with an embodiment of a universal bay system configured to accommodate sets of different devices.

### DESCRIPTION OF PARTICULAR EMBODIMENT(S)

In the following description, details are set forth by way of example to facilitate discussion of the disclosed subject matter. It should be apparent to a person of ordinary skill in the field, however, that the disclosed embodiments are exemplary and not exhaustive of all possible embodiments.

As used herein, a hyphenated form of a reference numeral refers to a specific instance of an element and the un-hyphenated form of the reference numeral refers to the collective or generic element. Thus, for example, device “114-1” refers to an instance of a device, which may be referred to collectively as devices “114” and any one of which may be referred to generically as device “114.”

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and one or more video displays. The information handling system may also include one or more buses operable to transmit communication between the various hardware components.

Embodiments disclosed herein include a universal bay system configurable to accommodate sets of different devices of an information handling system in a chassis.

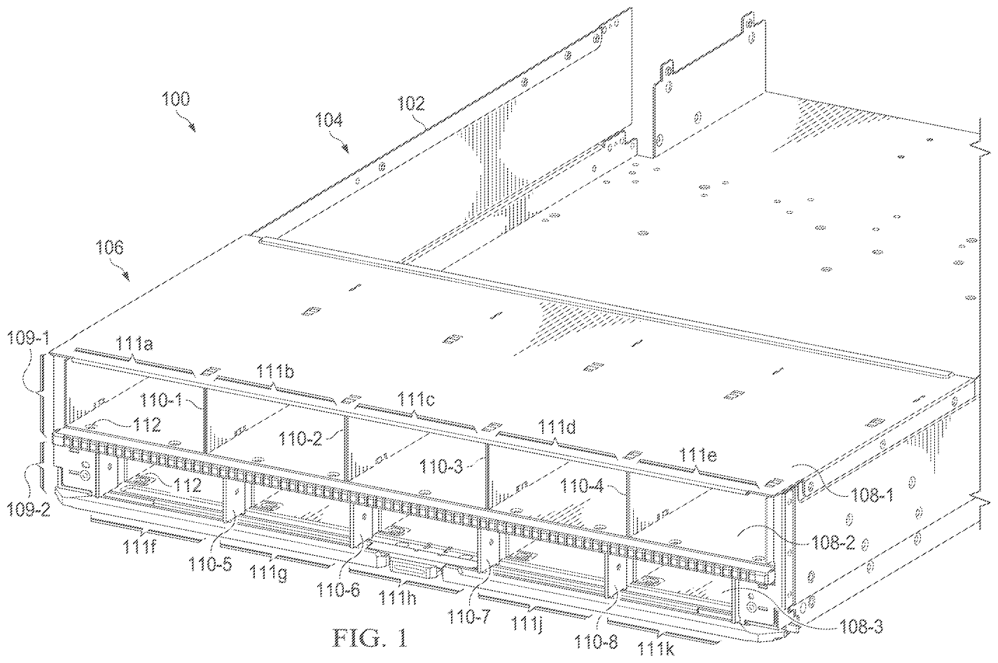

Embodiments disclosed herein are described with respect to information handling systems such as servers that are often installed in racks. Particular embodiments are best understood by reference to FIGS. 1, 2A-2C, 3A-3B, 4-5, 6A-6C and 7, wherein like numbers are used to indicate like and corresponding parts.

Turning to the drawings, FIG. 1 is a perspective view of a chassis with an embodiment of a universal bay system configurable to accommodate multiple sets of devices of an information handling system in various arrangements in the chassis.

Chassis 100 may be manufactured with two guide rails 102 to allow chassis 100 to be inserted or withdrawn from a server rack or other structure (not shown). Rear portion 104 may accommodate cabling, fans and other components for managing the performance of processing, storage, memory and network devices in chassis 100. Front portion 106 may comprise a universal bay system that is configurable to retain sets of devices in various arrangements for improved cooling or performance of information handling system.

As depicted in FIG. 1, embodiments of a universal bay system may include at least two support planes 108 coupled to each guide rail 102, wherein first support plane 108-1 and second support plane 108-2 are separated by a distance to form a first row 109-1 and second support plane 108-2 and third support plane 108-3 are separated by a distance to form a second row 109-2.

Embodiments of a universal bay system may further include a plurality of partitions 110 coupled to two adjacent support planes (e.g., support planes 108-1 and 108-2) to divide row 109 into bays 111. For example, partitions 110-1, 110-2, 110-3 and 110-4 divide row 109-1 into bays 111a, 111b, 111c, 111d and 111e and partitions 110-5, 110-6, 110-7 and 110-8 divide row 109-2 into bays 111f, 111g, 111h, 111j and 111k.

### PARTITION ASSEMBLY

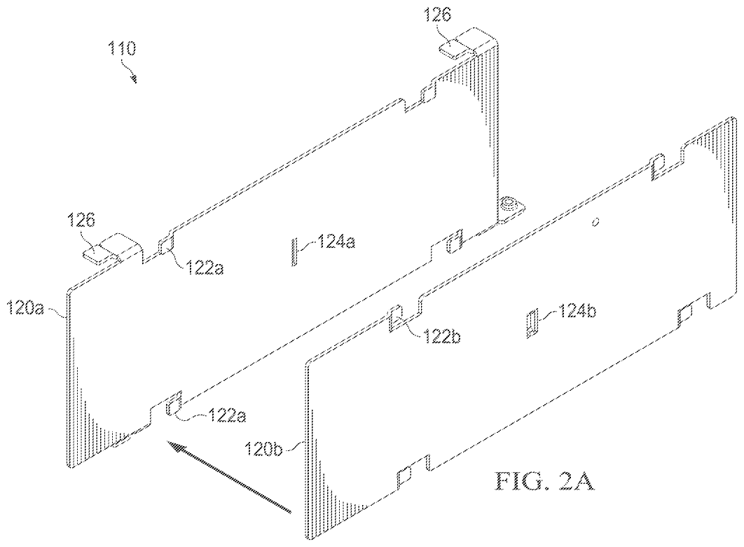

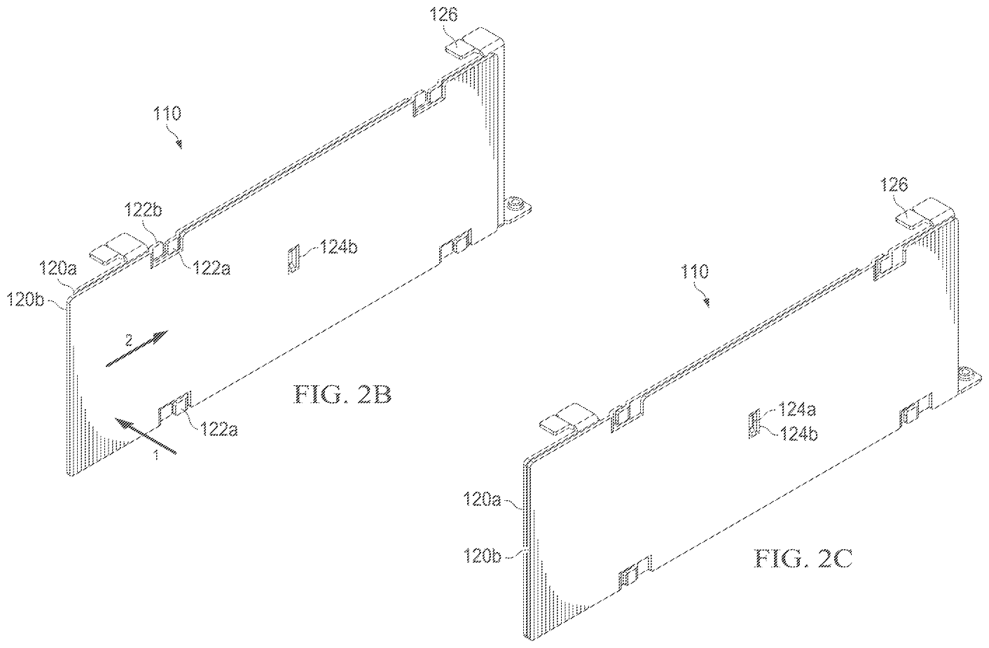

FIGS. 2A-2C are perspective views illustrating a method for assembling one embodiment of partition 110 from two walls 120 with wall connectors 122 and partition lock 124.

As depicted in FIG. 2A, partition 110 may be assembled from two walls 120, wherein a first wall 120a comprises first wall connectors 122a and a first portion 124a of partition lock 124 and second wall 120b comprises second wall connectors 122b and a second portion 124b of partition lock 124. One or more of first wall 120a and second wall 120b may be formed with support plane connectors 126, discussed in greater detail below.

As depicted in FIG. 2B, first wall 120a and second wall 120b may be positioned slightly offset such that first wall connectors 122a and second wall connectors 122b do not engage each other and partition lock 124 is not engaged.

As depicted in FIG. 2C, first wall 120a and second wall 120b may be translated relative to each other such that first wall connectors 122a engage second wall connectors 122b and first portion 124a of partition lock 124 engages second portion 124b of partition lock 124. Once partition lock 124 is engaged, partition 110 is formed and may be coupled to support planes 108.

### DEFINING BAYS

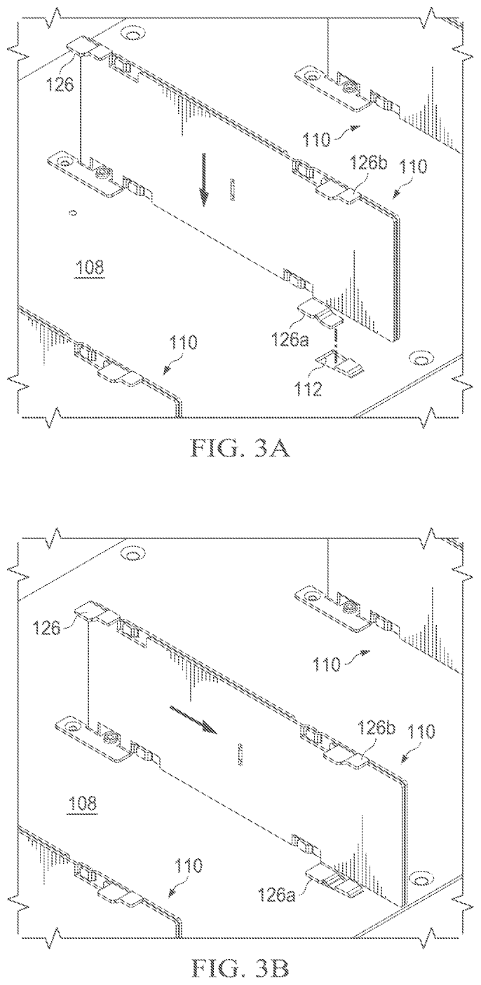

FIGS. 3A-3B are perspective views illustrating a method for positioning embodiments of partition 110 on a support plane 108 of chassis 100 to define bays in the universal bay system.

As depicted in FIG. 3A, partition 110 may be positioned with support plane connectors 126 in receiver 112.

As depicted in FIG. 3B, partition 110 may be translated relative to a support plane 108 to engage support plane connectors 126 with receivers 112 in support plane 108. In some embodiments, partition 110 may be positioned on support plane 108 and hardware may secure partition 110 to support plane 108. Since partitions 110 may lock together during assembly, less hardware may be needed to secure partitions 110 to support plane 108.

### ADDING DEVICE RETAINERS TO RETAIN SETS OF SPECIFIC DEVICES

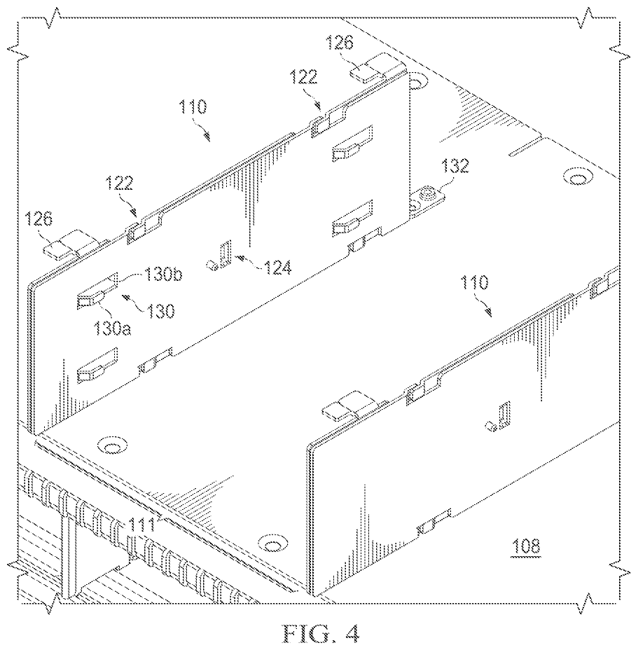

FIG. 4 is a perspective view of a portion of one embodiment of chassis 110 partially assembled with two partitions 110 forming a bay 111 on a support plane 108. In some embodiments, all features for a bay 111 are formed on partitions 110. As depicted in FIG. 4, partitions 110 may be formed with extensions 130. In some embodiments, extensions 130 may be formed as hooks.

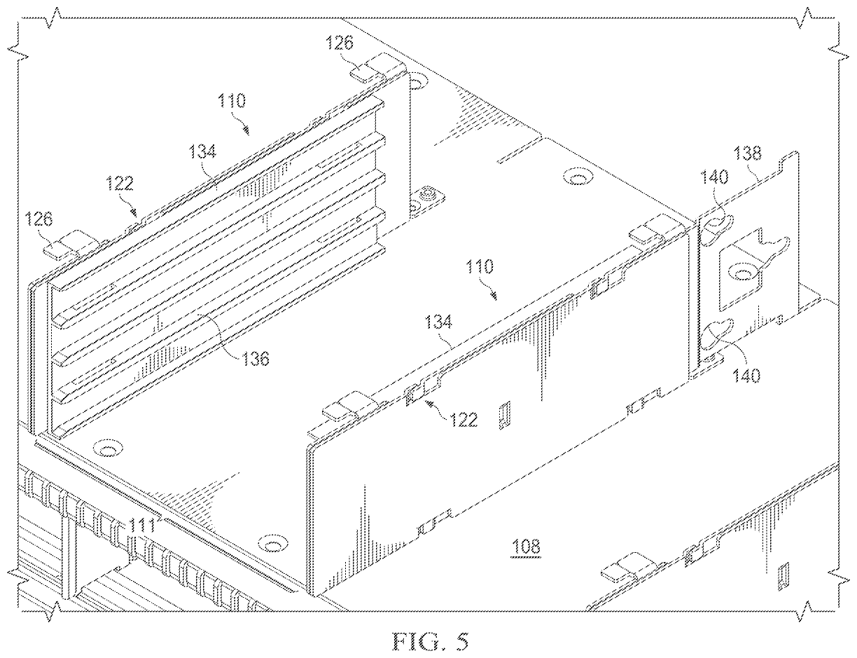

FIG. 5 is a perspective view of a portion of chassis 100 partially assembled with bay 111 formed by partitions 110 coupled to support plane 108 and device retainers 134 coupled to extensions 130a on two adjacent walls 120a, 120b.

As depicted in FIG. 5, device retainers 134 may comprise device rails 136 to allow easy installation and removal of devices 114 relative to bay 111. Chassis 100 may further include device support assembly bracket 138 for coupling to a device support assembly (not shown) configured for delivering power and communicating with each device 114 retained in bay 111. Device support assembly bracket 138 may comprise openings 140 such as keyhole openings to allow for easy installation and removal of a device support assembly.

### FINAL ASSEMBLY OF UNIVERSAL BAY SYSTEM

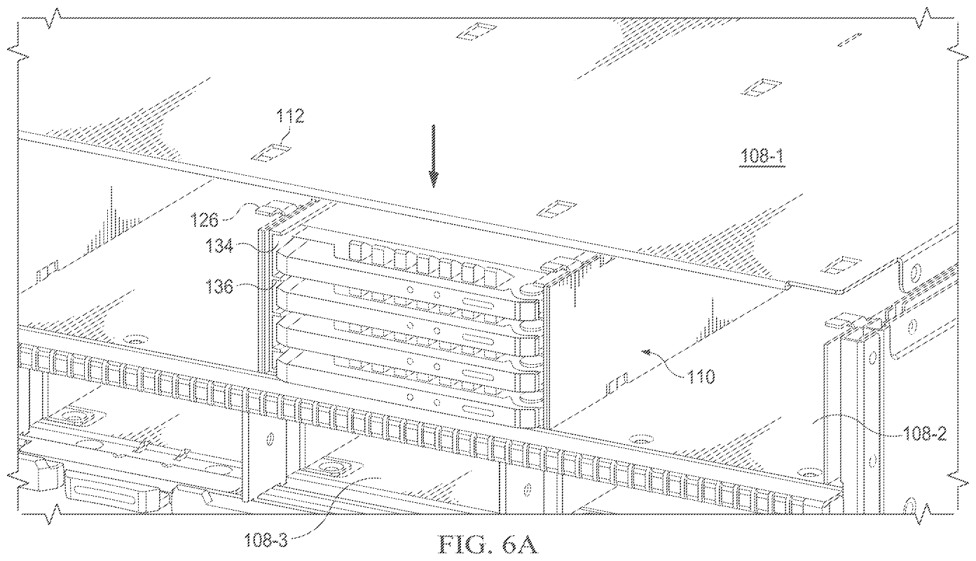

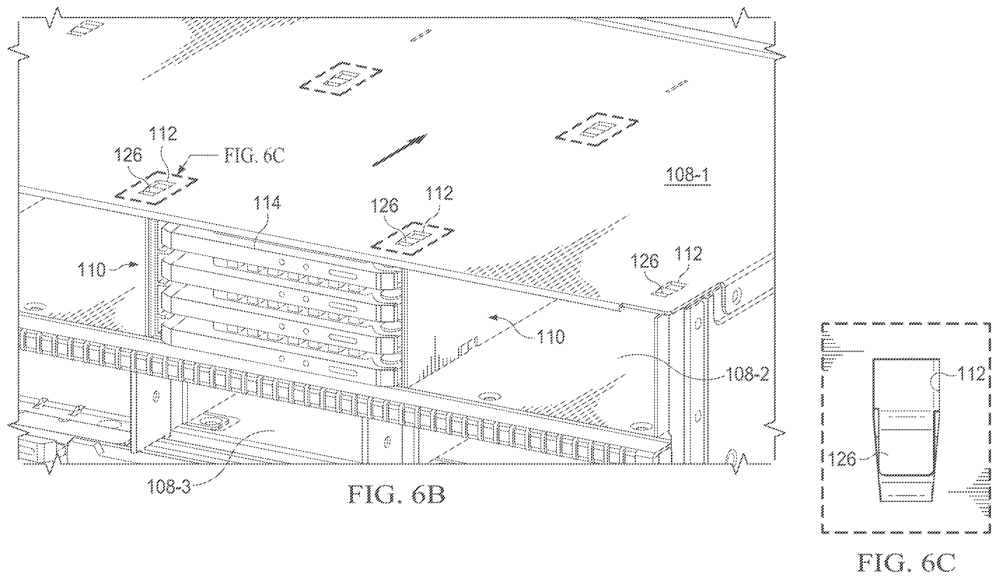

FIGS. 6A-6B are perspective views illustrating a method for positioning and coupling a second support plane 108 to a plurality of partitions 110.

As depicted in FIG. 6A, support plane 108-1 may be positioned with receivers 112 near support plane connectors 126 of each partition 110.

As depicted in FIG. 6B, support plane 108-1 may be translated relative to partitions 110 such that receivers 112 engage support plane connectors 126 of each partition 110.

FIG. 6C is a close up view of one embodiment of support plane connector 126 engaged with receiver 112, wherein chassis 100 is assembled. In some embodiments, support plane connectors 126 may be formed with a tapered profile for ease of alignment and a friction fit.

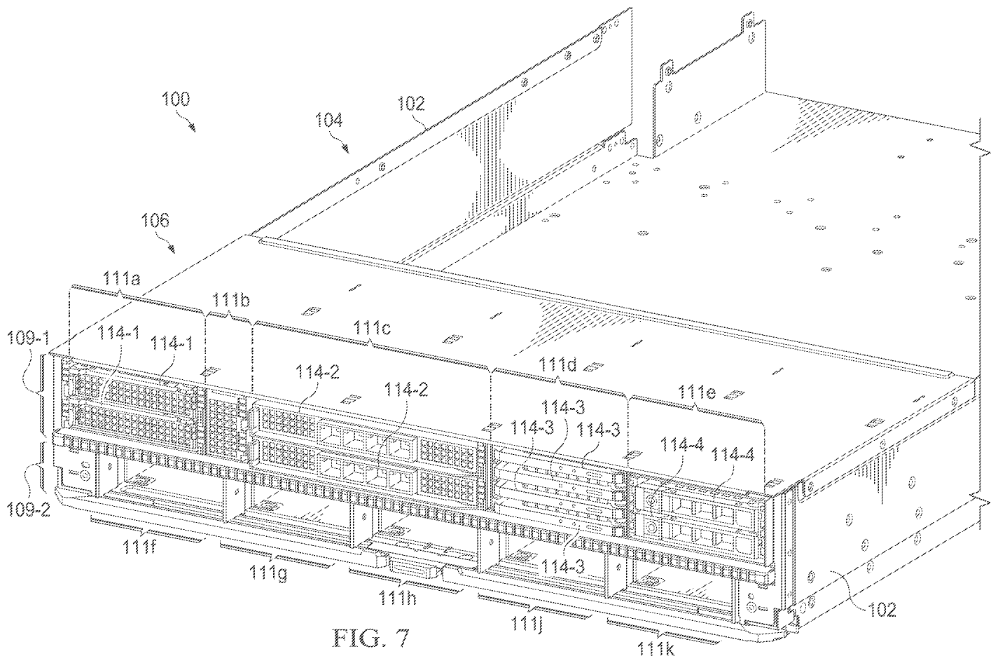

FIG. 7 is a perspective view of chassis 100 formed with one embodiment of a universal bay system in which chassis 100 is configured with row 109-1 configured with first bay 111a to retain a first set of devices 114-1, second bay 111b configured as a channel for fresh air, third bay 111c configured to retain a second set of devices 114-2, fourth bay 111d configured to retain a third set of devices 114-3, and fifth bay 111e configured to retain a fourth set of devices 114-4. Second row 109-2 may be configured with bays 111 configured for fresh air, retain power supply units (PSUs) or other devices 114.

Embodiments of a universal bay system described herein may include an array of mounting points to support various bay widths without the need to redesign chassis 100 for new devices or operating requirements. The distance between two adjacent partitions 110 and the device retainers 134 coupled to walls 120 may be configured to accommodate power supply units (PSU)s, I/O storage devices 114, and memory devices 114 of different form factors, with different airflow requirements and power supply requirements and ambient noise restrictions.

The above disclosed subject matter is to be considered illustrative, and not restrictive, and the appended claims are intended to cover all such modifications, enhancements, and other embodiments which fall within the true spirit and scope of the disclosure. Thus, to the maximum extent allowed by law, the scope of the disclosure is to be determined by the broadest permissible interpretation of the following claims and their equivalents, and shall not be restricted or limited by the foregoing detailed description.

What is claimed is:

1. A universal bay system for accommodating multiple sets of devices of an information handling system in a chassis, the universal bay comprising:
a pair of guide rails;
a plurality of support planes connected to the pair of guide rails, wherein a first support plane and an adjacent second support plane are separated by a distance to form a row; and
a plurality of partitions, wherein each partition comprises:
a first wall comprising a first wall connector and a support plane connector; and
a second wall comprising a second wall connector and a second support plane connector, wherein
the second wall connector engages the first wall connector to form the partition, and
each partition is coupled to the first support plane and the second support plane to divide the row into a plurality of bays.

2. The universal bay system of claim 1, further comprising a device retainer coupled to each wall corresponding to a bay, wherein device retainer is configured to retain of a set of devices in the bay.

3. The universal bay system of claim 2, wherein device retainer comprises a plurality of device rails.

4. The universal bay system of claim 3, wherein the bay is configured to retain a set of memory devices, processing devices, storage devices or networking devices.

5. The universal bay system of claim 3, wherein the bay is configured to retain a power supply unit (PSU).

6. The universal bay system of claim 3, wherein the bay is configured as a channel for airflow through the chassis.

7. The universal bay system of claim 1, further comprising a device support assembly bracket coupled to the partition.

8. A chassis for an information handling system comprising:
a rear portion for retaining cabling for one or more components of the information handling system;
a front portion comprising:
a pair of guide rails;
a plurality of support planes connected to the pair of guide rails, wherein a first support plane and an adjacent second support plane are separated by a distance to form a row; and
a plurality of partitions, wherein each partition comprises:
a first wall comprising a first wall connector and a support plane connector; and
a second wall comprising a second wall connector and a second support plane connector, wherein
the second wall connector engages the first wall connector to form the partition, and
each partition is coupled to the first support plane and the second support plane to divide the row into a plurality of bays.

9. The chassis of claim 8, further comprising a device retainer coupled to each wall corresponding to a bay, wherein device retainer is configured to retain of a set of devices in the bay.

10. The chassis of claim 9, wherein device retainer comprises a plurality of device rails.

11. The chassis of claim 10, wherein the bay is configured to retain a set of memory devices, processing devices, storage devices or networking devices.

12. The chassis of claim 10, wherein the bay is configured to retain a power supply unit (PSU).

13. The chassis of claim 10, wherein the bay is configured as a channel for airflow through the chassis.

14. The chassis of claim 8, further comprising a device support assembly bracket coupled to the partition.

15. A method for manufacturing a chassis of an information handling system, the method comprising:
coupling a first support plane to a first guide rail and a second guide rail;
forming a plurality of walls, wherein each wall comprises one of a first wall connector or a second wall connector for engaging the first wall connector;
assembling a plurality of partitions from the plurality of walls;
positioning the plurality of partitions on the first support plane, wherein the first support plane and the second support plane form a row;
coupling a second support plane to the plurality of partitions, wherein the plurality of partitions divide the row into bays.

16. The method of claim 15, further comprising coupling a device retainer to each wall corresponding to a bay, wherein the device retainer is configured to retain of a set of devices in the bay.

17. The method of claim 16, wherein device retainer comprises a plurality of device rails.

18. The method of claim 16, wherein the bay is configured to retain a set of memory devices, processing devices, storage devices or networking devices.

19. The method of claim 16, wherein the bay is configured to retain a power supply unit (PSU).

20. The method of claim 16, wherein the bay is configured as a channel for airflow through the chassis.
